(19) United States
(12) Patent Application Publication
(10) Pub. No.: US 2015/0102706 A1
(43) Pub. Date: Apr. 16, 2015

(54) PIEZOELECTRIC ELEMENT AND VIBRATOR INCLUDING THE SAME

(71) Applicant: SAMSUNG ELECTRO-MECHANICS CO., LTD., Suwon-si (KR)

(72) Inventors: Boum Seock Kim, Suwon-si (KR); Hui Sun Park, Suwon-si (KR); Jung Wook Seo, Suwon-si (KR)

(73) Assignee: SAMSUNG ELECTRO-MECHANICS CO., LTD., Suwon-si (KR)

(21) Appl. No.: 14/158,227

(22) Filed: Jan. 17, 2014

(30) Foreign Application Priority Data
Oct. 11, 2013 (KR) 10-2013-0121225

(51) Int. Cl. H01L 41/047; H01L 41/09

(52) U.S. Cl. CPC H01L 41/0472; H01L 41/09
USPC 310/317; 310/365

(57) ABSTRACT

There is provided a piezoelectric element including: a piezoelectric body including positive electrode layers and negative electrode layers alternately stacked on element layers; a polymer layer stacked on at least one surface of the piezoelectric body; a first external electrode stacked so as to contact the polymer layer; and a second external electrode disposed to be spaced apart from the first external electrode and stacked so as to contact the polymer layer.

### CROSS-REFERENCE TO RELATED APPLICATION

This application claims the benefit of Korean Patent Application No. 10-2013-0121225 filed on Oct. 11, 2013, with the Korean Intellectual Property Office, the disclosure of which is incorporated herein by reference.

### BACKGROUND

The present disclosure relates to a piezoelectric element and a vibrator including the same.

In various electronic devices such as a portable electronic device, for example a mobile phone, an e-book, a game machine, a portable multimedia player (PMP), or the like, a speaker, an actuator, and the like, a vibration function has been utilized for various purposes. Particularly, vibrators have been mounted in mobile devices such as a mobile phone, or the like, to thereby silently notify a user of call reception by transferring vibrations to the user. As the portable electronic devices have been multi-functionalized, the vibrator has also been required to have a small size and be multi-functional.

In accordance with the recent rise in demand simplified usage of electronic devices, a touch type device performing input by touching the electronic device are becoming increasingly widely used. A haptic feedback device encompasses a concept of reflecting intuitive user experience in an interface and further diversifying a feedback for the touch, in addition to a concept of performing input by touching the electronic device.

Meanwhile, a vibrator using a piezoelectric element has a faster response speed and may be driven at more varied frequencies, compared to an existing vibrator using eccentricity.

In addition, a multilayer type piezoelectric element has been used in the above-mentioned various electronic devices. However, in the case in which impact due to a drop or external force is applied to the electronic device, a crack may easily occur in the piezoelectric element.

In addition, in the case in which the crack occurs in the piezoelectric element, an operation region of an element part is significantly decreased thereby significantly decreasing vibration force, such that a fatal defect may occur rendering it impossible to use the electronic device.

In other words, in the case in which the crack occurs, power is applied from a circuit board only up to a portion at which the crack has occurred and is not applied to a portion beyond the portion at which the crack has occurred. That is, an effective electrode surface is decreased, such that an amount of vibration is reduced.

### RELATED ART DOCUMENT

(Patent Document 1) Korean Patent Laid-Open Publication No. 2008-0090618

### SUMMARY

An aspect of the present disclosure may provide a piezoelectric element capable of suppressing a decrease in an effective driving region even though a crack occurs, and a vibrator including the same.

According to an aspect of the present disclosure, a piezoelectric element may include: a piezoelectric body including positive electrode layers and negative electrode layers alternately stacked on element layers, respectively; a polymer layer stacked on at least one surface of the piezoelectric body; a first external electrode stacked so as to contact the polymer layer; and a second external electrode disposed to be spaced apart from the first external electrode and stacked so as to contact the polymer layer.

The first external electrode may be stacked so as to contact one side surface of the polymer layer and a horizontal surface connected to one side surface of the polymer layer.

The first external electrode may contact the positive electrode layer exposed to one side of the element layer.

The second external electrode may be stacked so as to contact the other side surface of the polymer layer.

The second external electrode may contact the negative electrode layer exposed to the other side surface of the element layer.

According to another aspect of the present disclosure, a vibrator may include: a plate; and a piezoelectric element fixed to the plate and connected to an external power supply through an electrode wire, wherein the piezoelectric element includes: a piezoelectric body including positive electrode layers and negative electrode layers alternately stacked on element layers, respectively; a polymer layer stacked on at least one surface of the piezoelectric body; a first external electrode stacked on the piezoelectric body so as to contact the polymer layer; and a second external electrode disposed to be spaced apart from the first external electrode and stacked on the piezoelectric body so as to contact the polymer layer.

The electrode wire may include a first electrode wire having one end bonded to the first external electrode and a second electrode wire having one end bonded to the plate.

The piezoelectric element may be bonded to the plate by a conductive adhesive.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view illustrating a piezoelectric element according to an exemplary embodiment of the present disclosure;

FIGS. 2 and 3 are views illustrating a configuration of the piezoelectric element according to an exemplary embodiment of the present disclosure;

FIG. 4 is a cross-sectional view illustrating the piezoelectric element according to an exemplary embodiment of the present disclosure;

FIG. 5 is a schematic perspective view illustrating a vibrator according to an exemplary embodiment of the present disclosure; and

FIG. 6 is a view illustrating a configuration of the vibrator according to an exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

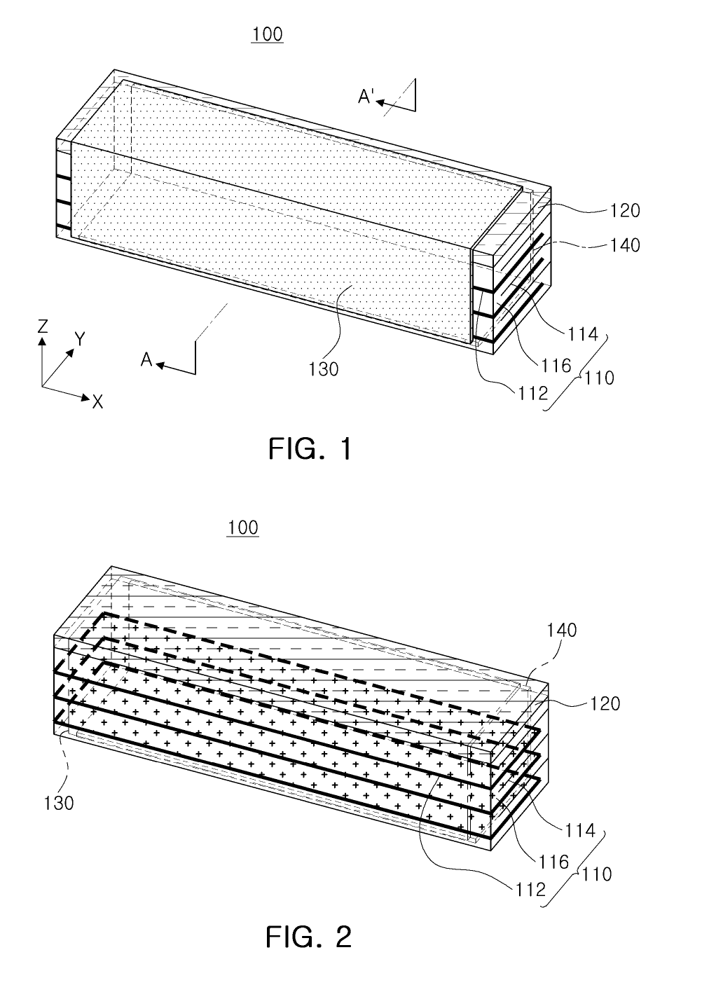

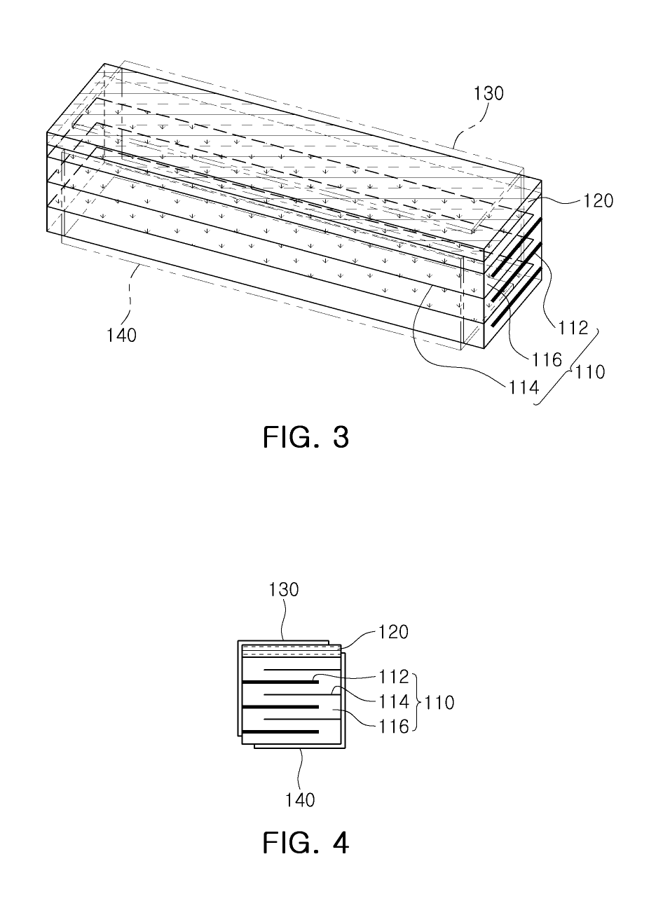

FIG. 1 is a schematic perspective view illustrating a piezoelectric element according to an exemplary embodiment of the present disclosure; FIGS. 2 and 3 are views illustrating a configuration of the piezoelectric element according to an exemplary embodiment of the present disclosure; and FIG. 4 is a cross-sectional view illustrating the piezoelectric element according to an exemplary embodiment of the present disclosure.

Referring to FIGS. 1 through 4, a piezoelectric element 100 according to an exemplary embodiment of the present disclosure may include a piezoelectric body 110, a polymer layer 120, a first external electrode 130, and a second external electrode 140 by way of example.

The piezoelectric body 110 may include positive electrode layers 112, negative electrode layers 114, and element layers 116, wherein the positive electrode layers 112 and the negative electrode layers 114 are alternately stacked on the element layers 116.

Meanwhile, the positive electrode layer 112 and the negative electrode layer 114 may each be formed of conductive metal. In addition, the element layer 116 may be formed of a piezoelectric material, preferably, lead zirconate titanate (PZT) ceramic.

Further, the piezoelectric body 110 may have, for example, a hexahedral shape.

Here, terms with respect to the respective outer surfaces of the piezoelectric body 100 will be defined. The outer surfaces of the piezoelectric body 110 may include an upper surface, a lower surface, both end surfaces, and both side surfaces. Both end surfaces refer to both end surfaces of the piezoelectric body 110 having the hexahedral shape in a length direction of the piezoelectric body 110, and both side surfaces refer to both surfaces of the piezoelectric body 110 in a width direction thereof.

Meanwhile, as illustrated in FIG. 1, a length direction refers to an X direction, a width direction refers to a Y direction, and a thickness direction refers to a Z direction.

The positive electrode layer 112 may be exposed to one side of the element layer 116. For example, the positive electrode layer 112 may be exposed to both end surfaces and one side surface of the element layer 116.

In addition, the negative electrode layer 114 may be exposed to the other side of the element layer 116. For example, the negative electrode layer 114 may be exposed to both end surfaces and the other side surface of the element layer 116.

The positive electrode layer 112 and the negative electrode layer 114 may each be formed of thin sheets. That is, the thin sheets may be alternately stacked on the element layers 116 to constitute the positive electrode layers 112 and the negative electrode layers 114.

Although the exemplary embodiment illustrates the case in which the positive electrode layer 112 and the negative electrode layer 114 are exposed to both end surfaces of the element layer 116 by way of example, the present disclosure is not limited thereto. That is, the positive electrode layer 112 may be exposed to only one side surface of the element layer 116 and the negative electrode layer 114 may be exposed to only the other side surface thereof.

The polymer layer 120 may be stacked on at least one surface of the piezoelectric body 110. For example, the polymer layer 120 may be stacked on the upper surface of the piezoelectric body 110. In addition, the polymer layer 120 may be formed of polyvinylidene fluoride (PVDF) based piezoelectric polymer.

Meanwhile, the polymer layer 120 may serve to prevent a crack from being spread in the case in which the crack occurs in the piezoelectric body 110. Therefore, the polymer layer 120 may prevent a short-circuit between the first and second external electrodes 130 and 140 and the positive and negative electrode layers 112 and 114.

In more detail, a crack may not occur in the polymer layer 120 stacked on the upper surface of the piezoelectric body 110 even though the crack occurs in the piezoelectric body 110. Therefore, power may be supplied from an external power supply to both of the positive electrode layer 112 and the negative electrode layer 114, separated into at least two parts due to the crack, through the first and second external electrodes 130 and 140 contacting the polymer layer 120.

For example, even in the case in which the positive electrode layer 112 is separated into two parts due to the crack occurring in the piezoelectric body 110, the crack may not occur in the polymer layer 120. Therefore, the power may be supplied to both of the two separated parts of the positive electrode layer 112 through the first external electrode 130 contacting the polymer layer 120.

Meanwhile, in the case in which the crack occurs in the piezoelectric body 110, the first external electrode 130 stacked on the piezoelectric body 110 may also be separated into two parts. In the case in which the first external electrode 130 is separated into two parts as described above, the power may be supplied from the external power to only one of the two separated parts of the first external electrode 130. Therefore, the power may only be supplied to the positive electrode layer 112 connected to any one of the two separated parts of the first external electrode 130.

However, the crack may not occur in the first external electrode 130 contacting the polymer layer 120 in which the crack does not occur as described above, and the power supplied to the first external electrode 130 may be supplied to both of the two separated parts of the first external electrode 130 disposed at a lower portion by the first external electrode 130 disposed at an upper portion contacting the polymer layer 120.

In addition, although the exemplary embodiment illustrates the case in which the polymer layer 120 is stacked on the upper surface of the piezoelectric body 110 way of example, the present disclosure is not limited thereto. That is, the polymer layer 120 may be stacked on at least one surface of the piezoelectric body 110. In other words, the polymer layer 120 may be stacked on a plurality of surfaces.

In addition, the polymer layer 120 may be stacked on the upper surface of the piezoelectric body 110 to protect the piezoelectric body 110 vulnerable to moisture.

The first external electrode 130 may be stacked so as to contact the polymer layer 120. For example, the first external electrode 130 may be stacked so as to contact one side surface of the polymer layer 120 and a horizontal surface connected to one side surface of the polymer layer 120. Further, the first external electrode 130 may be stacked on one side surface of the piezoelectric body 110.

In other words, the first external electrode 130 may be stacked on an upper surface and one side surface of a coupled body (hexahedral) formed by the piezoelectric body 110 and the polymer layer 120 stacked on the upper surface of the piezoelectric body 110.

In addition, the first external electrode 130 may contact the positive electrode layer 112 exposed to one side surface of the element layer 116.

Therefore, the power may be supplied from the external power supply to the positive electrode layer 112. In addition, since the first external electrode 130 contacts the polymer layer 120 as described above, even though a crack occurs, the power may be stably supplied to an entire region of the positive electrode layer 112.

The second external electrode 140 may be disposed so as to be spaced apart from the first external electrode 130 and may be stacked so as to contact the polymer layer 120. For example, the second external electrode 140 may be stacked so as to contact the other side surface of the polymer layer 120. Further, the second external electrode 140 may be stacked on the other side surface and the lower surface of the piezoelectric body 110.

In other words, the second external electrode 140 may be stacked on the other side surface and a lower surface of the coupled body (hexahedral) formed by the piezoelectric body 110 and the polymer layer 120 stacked on the upper surface of the piezoelectric body 110.

In addition, the second external electrode 140 may contact the negative electrode layer 114 exposed to the other side surface of the element layer 116.

Therefore, the power may be supplied from the external power supply to the negative electrode layer 114. In addition, since the second external electrode 140 contacts the polymer layer 120 as described above, even though a crack occurs, the power may be stably supplied to an entire region of the negative electrode layer 114.

As described above, the spread of the crack may be prevented by the polymer layer 120 to suppress a decrease in an effective driving region due to the crack.

That is, even though the crack occurs in the piezoelectric body 110, it may not spread to the polymer layer 120, and portions of the first and second external electrodes 130 and 140 may contact the polymer layer 120, such that the power may be supplied to an entire region through the portions of the first and second external electrodes 130 and 140 contacting the polymer layer 120.

Therefore, even though the positive electrode layer 112 and the negative electrode layer 114 are each separated into a plurality of parts due to the crack, the power may be supplied to the entirety of the positive electrode layer 112 and the negative electrode layer 114.

As a result, a phenomenon in which the power is not supplied, such that the effective driving region is decreased, may be prevented.

Hereinafter, a vibrator according to an exemplary embodiment of the present disclosure will be described with reference to the accompanying drawings.

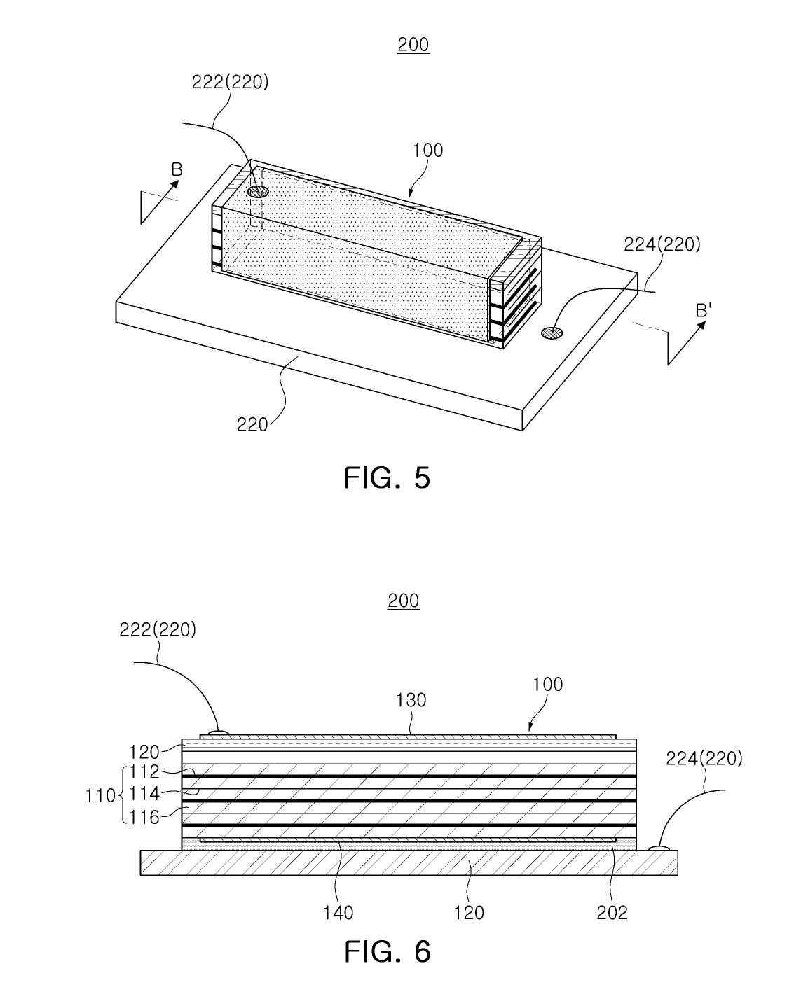

FIG. 5 is a schematic perspective view illustrating a vibrator according to an exemplary embodiment of the present disclosure; and FIG. 6 is a view illustrating a configuration of the vibrator according to an exemplary embodiment of the present disclosure.

Referring to FIGS. 5 and 6, a vibrator 200 according to an exemplary embodiment of the present disclosure may include a plate 210 and the piezoelectric element 100 by way of example.

The plate 210 may be formed of a thin plate having a rectangular shape when viewed from the top. In addition, in the case in which the piezoelectric element 110 is deformed due to power supplied thereto, the plate 210 may be deformed together with the piezoelectric element 100 to generate vibrations.

Meanwhile, the plate 210 may be larger than the piezoelectric element 100, and the piezoelectric element 100 may be installed on the plate 210 so as to be disposed at approximately a central portion of the plate 210.

In addition, the plate 210 may have an electrode wire 220 coupled to one side thereof. The electrode wire 220 may include a first electrode wire 222 having one end bonded to the first external electrode 130 and a second electrode wire 224 having one end bonded to one side of the plate 210.

In addition, the second electrode wire 224 may be bonded to one side of the plate 210.

Meanwhile, the plate 210 may be formed of a conductive material. That is, the plate 210 may be formed of the conductive material so that power supplied through the second electrode wire 224 may be supplied to the second external electrode 140 through the plate 210.

The piezoelectric element 100 may be fixed to the plate 210 by a conductive adhesive 202 and may be connected to the external power supply through the electrode wire 220.

That is, the first electrode wire 222 may be bonded to an upper portion of the first external electrode 130, such that the power is supplied to the first external electrode 130 through the first electrode wire 222. In addition, the second electrode wire 224 may supply the power to the second external electrode 140. That is, the second electrode wire 224 may be bonded to the plate 210, such that the power is supplied to the second external electrode 140 through the plate 210 and the conductive adhesive 202.

To this end, the adhesive for bonding the piezoelectric element 100 and the plate 210 may be formed of a conductive material.

Here, the piezoelectric element 100 will be described again. The piezoelectric element 100 may include the piezoelectric body 110, the polymer layer 120, the first external electrode 130, and the second external electrode 140 by way of example.

The piezoelectric body 110 may include the positive electrode layers 112, the negative electrode layers 114, and the element layers 116, wherein the positive electrode layers 112 and the negative electrode layers 114 are alternately stacked on the element layers 116.

Meanwhile, the positive electrode layer 112 and the negative electrode layer 114 may each be formed of conductive metal. In addition, the element layer 116 may be formed of a piezoelectric material, preferably, lead zirconate titanate (PZT) ceramic.

Further, the piezoelectric body 110 may have, for example, a hexahedral shape.

The positive electrode layer 112 may be exposed to one side of the element layer 116. For example, the positive electrode layer 112 may be exposed to both end surfaces and one side surface of the element layer 116.

In addition, the negative electrode layer 114 may be exposed to the other side of the element layer 116. For example, the negative electrode layer 114 may be exposed to both end surfaces and the other side surface of the element layer 116.

The positive electrode layer 112 and the negative electrode layer 114 may each be formed of thin sheets. That is, the thin sheets may be alternately stacked on the element layers 116 to constitute the positive electrode layers 112 and the negative electrode layers 114.

Although the exemplary embodiment illustrate the case in which the positive electrode layer 112 and the negative electrode layer 114 are exposed to both end surfaces of the element layer 116 by way of example, the present disclosure is not limited thereto. That is, the positive electrode layer 112 may be exposed to only one side surface of the element layer 116 and the negative electrode layer 114 may be exposed to only the other side surface thereof.

The polymer layer 120 may be stacked on at least one surface of the piezoelectric body 110. For example, the polymer layer 120 may be stacked on the upper surface of the piezoelectric body 110. In addition, the polymer layer 120 may be formed of PVDF based piezoelectric polymer.

Meanwhile, the polymer layer 120 may serve to prevent the crack from being spread in the case in which the crack occurs in the piezoelectric body 110. Therefore, the polymer layer 120 may prevent the short-circuit between the first and second external electrodes 130 and 140 and the positive and negative electrode layers 112 and 114.

In more detail, the crack may not occur in the polymer layer 120 stacked on the upper surface of the piezoelectric body 110 even though the crack occurs in the piezoelectric body 110. Therefore, the power may be supplied from the external power supply to both of the positive electrode layer 112 and the negative electrode layer 114, separated into at least two parts due to the crack, through the first and second external electrodes 130 and 140 contacting the polymer layer 120.

For example, even in the case in which the positive electrode layer 112 is separated into two parts due to the crack occurring in the piezoelectric body 110, the crack may not occur in the polymer layer 120. Therefore, the power may be supplied to both of the two separated parts of the positive electrode layer 112 through the first external electrode 130 contacting the polymer layer 120.

Meanwhile, in the case in which the crack occurs in the piezoelectric body 110, the first external electrode 130 stacked on the piezoelectric body 110 may also be separated into two parts. In the case in which the first external electrode 130 is separated into two parts as described above, the power may be supplied from the external power to only one of the two separated parts of the first external electrode 130. Therefore, the power may only be supplied to the positive electrode layer 112 connected to any one of the two separated parts of the first external electrode 130.

However, the crack may not occur in the first external electrode 130 contacting the polymer layer 120 in which the crack does not occur as described above, and the power supplied to the first external electrode 130 may be supplied to both of the two separated parts of the first external electrode 130 disposed at the lower portion by the first external electrode 130 disposed at an upper portion contacting the polymer layer 120.

In addition, although the exemplary embodiment illustrates the case in which the polymer layer 120 is stacked on the upper surface of the piezoelectric body 110 by way of example, the present disclosure is not limited thereto. That is, the polymer layer 120 may be stacked on at least one surface of the piezoelectric body 110. In other words, the polymer layer 120 may be stacked on a plurality of surfaces.

In addition, the polymer layer 120 may be stacked on the upper surface of the piezoelectric body 110 to protect the piezoelectric body 110 vulnerable to moisture.

The first external electrode 130 may be stacked so as to contact the polymer layer 120. For example, the first external electrode 130 may be stacked so as to contact one side surface of the polymer layer 120 and a horizontal surface connected to one side surface of the polymer layer 120. Further, the first external electrode 130 may be stacked on one side surface of the piezoelectric body 110.

In other words, the first external electrode 130 may be stacked on an upper surface and one side surface of a coupled body (hexahedral) formed by the piezoelectric body 110 and the polymer layer 120 stacked on the upper surface of the piezoelectric body 110.

In addition, the first external electrode 130 may contact the positive electrode layer 112 exposed to one side surface of the element layer 116.

Therefore, the power may be supplied from the external power supply to the positive electrode layer 112. In addition, since the first external electrode 130 contacts the polymer layer 120 as described above, even though a crack occurs, the power may be stably supplied to an entire region of the positive electrode layer 112.

The second external electrode 140 may be disposed so as to be spaced apart from the first external electrode 130 and may be stacked so as to contact the polymer layer 120. For example, the second external electrode 140 may be stacked so as to contact the other side surface of the polymer layer 120. Further, the second external electrode 140 may be stacked on the other side surface and the lower surface of the piezoelectric body 110.

In other words, the second external electrode 140 may be stacked on the other side surface and a lower surface of the coupled body (hexahedral) formed by the piezoelectric body 110 and the polymer layer 120 stacked on the upper surface of the piezoelectric body 110.

In addition, the second external electrode 140 may contact the negative electrode layer 114 exposed to the other side surface of the element layer 116.

Therefore, the power may be supplied from the external power supply to the negative electrode layer 114. In addition, since the second external electrode 140 contacts the polymer layer 120 as described above, even though a crack occurs, the power may be stably supplied to an entire region of the negative electrode layer 114.

As set forth above, according to an exemplary embodiment of the present disclosure, the spread of the crack may be prevented by the polymer layer 120 to suppress a decrease in an effective driving region due to the crack. Therefore, a decrease in an amount of vibrations due to the crack may be prevented.

While exemplary embodiments have been shown and described above, it will be apparent to those skilled in the art that modifications and variations could be made without departing from the spirit and scope of the present disclosure as defined by the appended claims.

What is claimed is:

1. A piezoelectric element, comprising:
a piezoelectric body including positive electrode layers and negative electrode layers alternately stacked on element layers;
a polymer layer stacked on at least one surface of the piezoelectric body;
a first external electrode stacked so as to contact the polymer layer; and
a second external electrode disposed to be spaced apart from the first external electrode and stacked so as to contact the polymer layer.

2. The piezoelectric element of claim 1, wherein the first external electrode is stacked so as to contact one side surface of the polymer layer and a horizontal surface connected to one side surface of the polymer layer.

3. The piezoelectric element of claim 2, wherein the first external electrode contacts the positive electrode layer exposed to one side of the element layer.

4. The piezoelectric element of claim 1, wherein the second external electrode is stacked so as to contact the other side surface of the polymer layer.

5. The piezoelectric element of claim 4, wherein the second external electrode contacts the negative electrode layer exposed to the other side surface of the element layer.

6. A vibrator comprising:
a plate; and
a piezoelectric element fixed to the plate and connected to an external power supply through an electrode wire,
wherein the piezoelectric element includes:
a piezoelectric body including positive electrode layers and negative electrode layers alternately stacked on element layers;
a polymer layer stacked on at least one surface of the piezoelectric body;
a first external electrode stacked on the piezoelectric body so as to contact the polymer layer; and
a second external electrode disposed to be spaced apart from the first external electrode and stacked on the piezoelectric body so as to contact the polymer layer.

7. The vibrator of claim 6, wherein the electrode wire includes a first electrode wire having one end bonded to the first external electrode and a second electrode wire having one end bonded to the plate.

8. The vibrator of claim 6, wherein the piezoelectric element is bonded to the plate by a conductive adhesive.

9. The vibrator of claim 6, wherein the first external electrode is stacked so as to contact one side surface of the polymer layer and a horizontal surface connected to one side surface of the polymer layer, and
the first external electrode contacts the positive electrode layer exposed to one side of the element layer.

10. The vibrator of claim 6, wherein the second external electrode is stacked so as to contact the other side surface of the polymer layer, and
the second electrode contacts the negative electrode layer exposed to the other side surface of the element layer.
